(19) United States
(12) Patent Application Publication
(10) Pub. No.: US 2026/0157056 A1
(43) Pub. Date: Jun. 4, 2026

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventors: Cheng WANG, Wuhan, Hubei (CN); Liang YE, Wuhan, Hubei (CN)

(73) Assignee: Wuhan China Star Optoelectronics Semiconductor Display Technology Co., Ltd., Wuhan, Hubei (CN)

(21) Appl. No.: 18/695,890

(22) PCT Filed: Feb. 26, 2024
(86) PCT No.: PCT/CN2024/078574

§ 371 Date: Mar. 27, 2024

(30) Foreign Application Priority Data
Feb. 8, 2024 (CN) 202410179046.8

(51) Int. Cl. H10K 59/131; H10K 59/121

(52) U.S. Cl. CPC H10K 59/131; H10K 59/1213

(57) ABSTRACT

A display panel and a display device are provided. A pixel driving circuit of the display panel includes a switch transistor, a driving transistor, a compensation transistor, a first reset transistor, and a first capacitor connected to each other. A first electrode of the first reset transistor is connected to a first reset signal line, a first plate of the first capacitor is connected to the first reset signal line, and a second plate of the first capacitor is connected to a first high potential line.

### TECHNICAL FIELD

The present application relates to a field of display technology, and in particular, to a display panel and a display device.

### DESCRIPTION OF RELATED ART

OLED (Organic Light-Emitting Diode) display technology is a new type of display technology that has gradually attracted attention due to its unique advantages such as low power consumption, high saturation, fast response time, and wide viewing angle, occupying a certain position in the field of panel display technology.

In related technology, the pixel driving circuit of an OLED display panel usually includes a switch transistor, a driving transistor, a compensation transistor, and a reset transistor. A drain of the switch transistor is connected to a data line, and a drain of the reset transistor is connected to a reset signal line. There is an overlapping area between the data line and the reset signal line. When a voltage input through the data line changes, a coupling capacitance between the data line and the reset signal line causes the voltage signal on the reset signal line to change. This, in turn, causes an output voltage at a source of the reset transistor to change, which prevents a voltage at a reset node from being reset to a reference voltage, leading to abnormal anomalies on the display panel.

### SUMMARY OF INVENTION

The present application provides a display panel and a display device to improve the technical issue of display anomalies in conventional display panels.

In order to solve the above issue, the present application provides technical solutions as below:

The present application provides a display panel, including a plurality of sub-pixel units, each of the sub-pixel units provided with a light-emitting device and a pixel driving circuit connected to the light-emitting device, wherein the pixel driving circuit includes:
a switch transistor, a first electrode of the switch transistor connected to a first data signal line and a second electrode of the switch transistor connected to a first node;
a driving transistor, a first electrode of the driving transistor connected to the first node, a second electrode of the driving transistor connected to a second node, and a driving gate of the driving transistor connected to a third node;
a compensation transistor, a first electrode of the compensation transistor connected to the third node, and a second electrode of the compensation transistor connected to the second node;
a first reset transistor, a first electrode of the first reset transistor connected to a first reset signal line, and a second electrode of the first reset transistor connected to the first node; and
a first capacitor, a first plate of the first capacitor connected to the first reset signal line, and a second plate of the first capacitor connected to a first high potential line.

The present application further provides a display device, including a display panel, the display panel including a plurality of sub-pixel units, each of the sub-pixel units provided with a light-emitting device and a pixel driving circuit connected to the light-emitting device, wherein the pixel driving circuit includes:
a switch transistor, a first electrode of the switch transistor connected to a first data signal line and a second electrode of the switch transistor connected to a first node;
a driving transistor, a first electrode of the driving transistor connected to the first node, a second electrode of the driving transistor connected to a second node, and a driving gate of the driving transistor connected to a third node;
a compensation transistor, a first electrode of the compensation transistor connected to the third node, and a second electrode of the compensation transistor connected to the second node;
a first reset transistor, a first electrode of the first reset transistor connected to a first reset signal line, and a second electrode of the first reset transistor connected to the first node; and
a first capacitor, a first plate of the first capacitor connected to the first reset signal line, and a second plate of the first capacitor connected to a first high potential line.

### BRIEF DESCRIPTION OF DRAWINGS

FIG. 1 is a schematic structural view of a display panel of the present application.

FIG. 2 is an equivalent circuit diagram of a pixel driving circuit in the display panel of the present application.

FIG. 3 is a schematic view illustrating film layers in the display panel of the present application.

FIG. 4 is a film layer diagram of a first gate layer in the display panel of the present application.

FIG. 5 is a film layer diagram of a first active layer in the display panel of the present application.

FIG. 6 is a laminated film layer diagram of the first gate layer and the first active layer in the display panel of the present application.

FIG. 7 is a film layer diagram of a second gate layer in the display panel of the present application.

FIG. 8 is a laminated film layer diagram of the first gate layer and the second gate layer in the display panel of the present application.

FIG. 9 is a film layer diagram of a second active layer in the display panel of the present application.

FIG. 10 is a film layer diagram of a third gate layer in the display panel of the present application.

FIG. 11 is a film layer diagram illustrating the first active layer, the second active layer, the second gate layer, and the third gate layer in the display panel of the present application.

FIG. 12 is a film layer diagram of a first source-drain layer in the display panel of the present application.

FIG. 13 is film layer diagram illustrating the first gate layer, the third gate layer, the first active layer, the second active layer, and the first source-drain layer in the display panel of the present application.

FIG. 14 is a film layer diagram illustrating the second active layer, the second gate layer, and the first source-drain layer in the display panel of the present application.

FIG. 15 is a film layer diagram illustrating the first gate layer, the second gate layer, the third gate layer, the first active layer, the second active layer, and the first source-drain layer in the display panel of the present application.

FIG. 16 is a first type of film layer diagram of a second source-drain layer in the display panel of the present application.

FIG. 17 shows a first type of laminated film layer diagram illustrating the first gate layer, the first source-drain layer, and the second source-drain layer in the display panel of this application.

FIG. 18 is a first type of laminated film layer diagram of the pixel driving circuit in the present application.

FIG. 19 is a connection diagram of different sub-pixel units and different data lines in the display panel of the present application.

FIG. 20 is a second type of film layer diagram of the second source-drain layer in the display panel of the present application.

FIG. 21 is a second type of laminated film layer diagram of the first gate layer, the first source-drain layer, and the second source-drain layer in the display panel of the present application.

FIG. 22 is a film layer diagram of a third source-drain layer in the display panel of the present application.

FIG. 23 is a laminated film layer diagram of the second source-drain layer and the third source-drain layer in the display panel of the present application.

FIG. 24 is a fourth type of laminated film layer diagram of the pixel driving circuit in the present application.

FIG. 25 is a film layer diagram of the third source-drain layer across multiple sub-pixel units in the display panel of the present application.

FIG. 26 is a connection diagram of a third reset signal line, a second reset signal line, a first reset signal line, and a fourth reset signal line in the display panel of the present application.

FIG. 27 is a laminated film layer diagram of the third source-drain layer, data signal lines, and anodes of the light-emitting devices in the display panel of the present application.

### DETAILED DESCRIPTION OF EMBODIMENTS OF THE INVENTION

The following provides a clear and complete description of the technical solution in the embodiments of the present application, in conjunction with the accompanying drawings of the embodiments. Obviously, the described embodiments are just a part of the embodiments of this application, and not all of them. Based on the embodiments in this application, all other embodiments obtained by those skilled in the art without making creative efforts fall within the protection scope of this application. Furthermore, it should be understood that the specific implementations described here are only for the purpose of illustration and explanation of this application and are not intended to limit this application. In this application, unless stated otherwise, directional terms such as “up” and “down” generally refer to the up and down in the actual use or working state of the device, specifically to the directions in the drawings; while “inner” and “outer” refer to the outline of the device.

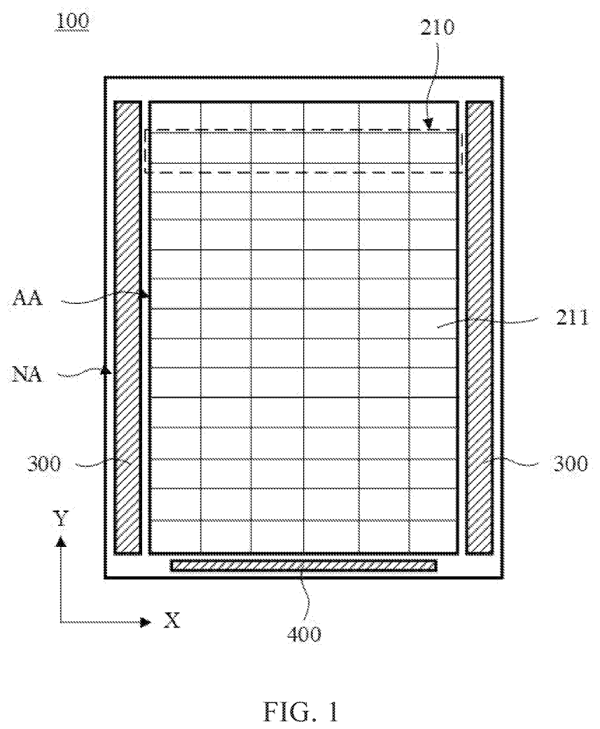

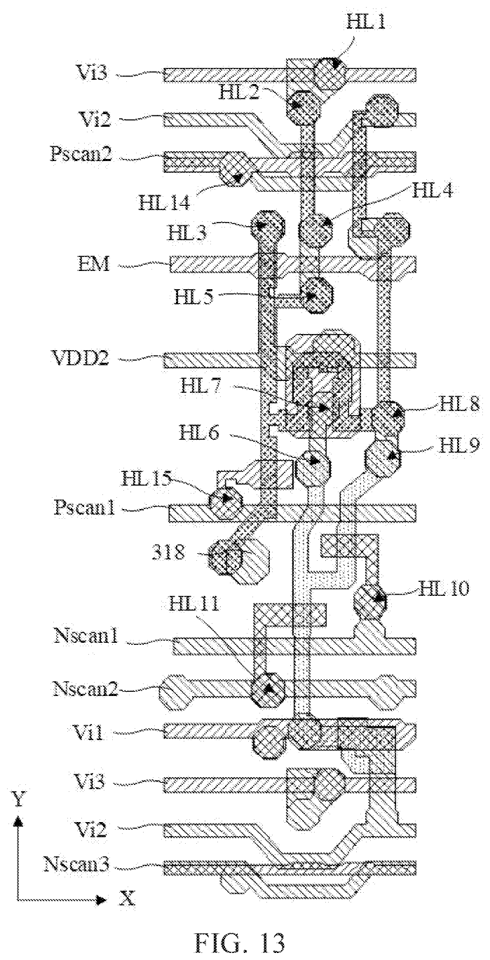

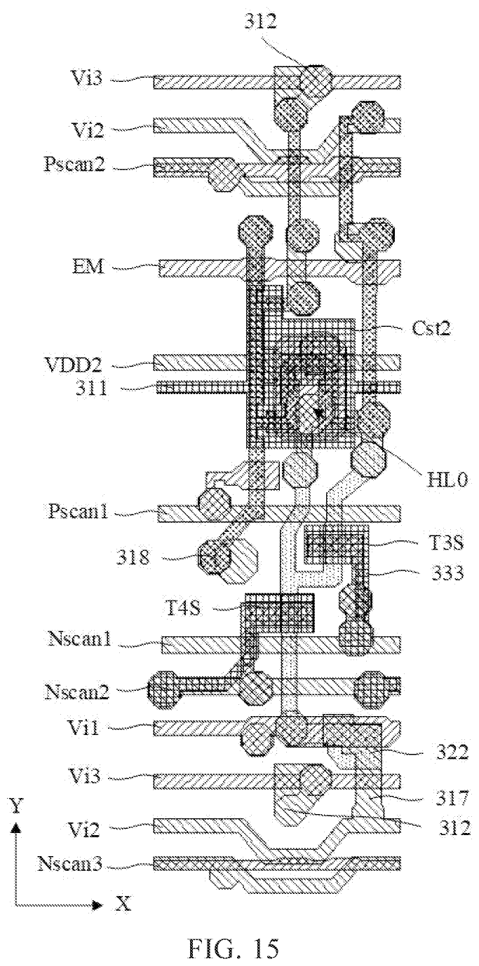

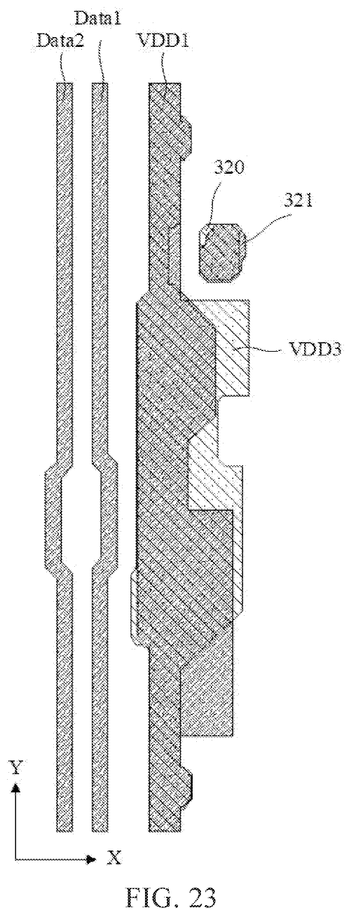

Referring to FIGS. 1 to 26, the present application provides a display panel 100. The display panel 100 can include a display part 200 and a gate driving circuit 300 disposed on one side of the display part 200. The gate driving circuit 300 is used to input control signals to the display part 200.

In this embodiment, as shown in FIG. 1, the display part 200 includes multiple sub-pixel rows 210, each sub-pixel row 210 includes multiple sub-pixel units 211, and each sub-pixel unit 211 is provided with a light-emitting device 211b and a pixel driving circuit 211a connected to the light-emitting device 211b. The gate driving circuit 300 is used to input gate control signals to transistors in the pixel driving circuit 211a.

In this embodiment, the pixel driving circuit 211a can include a switch transistor T2, a driving transistor T1, a compensation transistor T3, and a first reset transistor T8 which are interconnected. A first electrode of the switch transistor T2 is connected to a first data signal line Data1, a second electrode of the switch transistor T2 is connected to a first node A, a first electrode of the driving transistor T1 is connected to the first node A, a second electrode of the driving transistor T1 is connected to a second node B, and a drive gate T1G of the driving transistor T1 is connected to a third node Q. A first electrode of the compensation transistor T3 is connected to the third node Q, a second electrode of the compensation transistor T3 is connected to the second node B, and a compensation gate T3G of the compensation transistor T3 is connected to a first scan signal line Nscan1. A first electrode of the first reset transistor T8 is connected to a first reset signal line Vi3, and a second electrode of the first reset transistor T8 is connected to the first node A.

In the present embodiment, the pixel driving circuit 211a also includes a first capacitor C1, where a first plate of the first capacitor C1 is connected to the first reset signal line Vi3, and a second plate of the first capacitor C1 is connected to a first high potential line VDD1.

The present application improves a coupling resistance of the first reset signal line Vi3 by setting the first capacitor C1 between the first reset signal line Vi3 and the first high potential line VDD1. By utilizing a high potential of the first high potential line VDD1, the stability of a reset signal transmitted by the first reset signal line Vi3 is enhanced. This prevents abnormal output voltage at an output end of the first reset transistor T8, ensuring that a voltage at a reset node between the switch transistor T2 and the first reset transistor T8 is reset to a reference voltage, thereby addressing the technical issue of display anomalies in the display panel.

It should be noted that the light-emitting device 211b in the present application can be an organic light-emitting diode (OLED), a Mini LED, a Micro LED, a conventional-sized LED, or other types of light sources.

Now, a description of the technical solution of this application is provided in conjunction with specific embodiments.

Please refer to FIG. 1. The display panel 100 includes a display area AA and a non-display area NA located adjacent to the display area AA. The display part 200 is arranged within the display area AA. Optionally, the non-display area NA surrounds the display area AA, enclosing the display area AA within the non-display area NA. The display area AA is an area within the display panel 100 designated for performing a display function, and the display area AA includes multiple sub-pixel units 211 that facilitate the display function. The non-display area NA can serve as a frame region of the display panel 100. In the non-display area NA, there can be provided with functional components that support display capabilities of the sub-pixel units 211.

Please refer to FIG. 1. On a lower side of the display area AA, there are bonding terminals 400. The bonding terminals 400 can be connected to external circuits. The bonding terminals 400 transmit signals input from the external circuits to the data lines, thereby driving the display panel 100 to show images. For example, the bonding terminals 400 can be bonded to a chip or a flip-chip film, providing power supply and driving signals for the display panel 100.

In the present embodiment, the gate driving circuit 300 is located within the non-display area NA, and it can also be positioned on both sides of the display area AA. The gate driving circuit 300 can include multiple gate driving units connected in cascade, which can be arranged along a first direction X. The structure of the gate driving units is not specifically limited in this application.

In the present embodiment, within the display area AA, multiple light-emitting devices 211b and their respective pixel driving circuits 211a that drive these light-emitting devices 211b can be arrayed. The pixel driving circuits 211a can be of various types, such as 7T1C (7 transistors, 1 capacitor), 7T2C (7 transistors, 2 capacitors), 8T2C (8 transistors, 2 capacitors), 8T3C (8transistors, 3 capacitors), 8T4C (8 transistors, 4 capacitors), etc. The following embodiments specifically describe the implementation using the 8T3C pixel driving circuit 211a as an example.

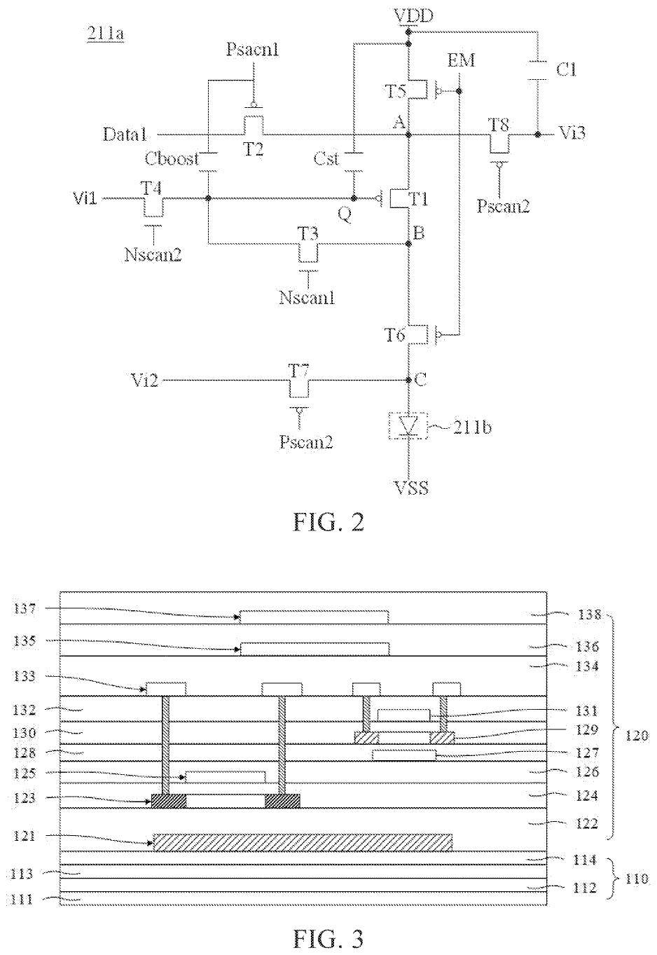

Please refer to FIG. 2, the pixel driving circuit 211a can include a switch transistor T2, a driving transistor T1, a compensation transistor T3, a third reset transistor T4, a second reset transistor T7, a first reset transistor T8, a first light-emitting transistor T5, a second light-emitting transistor T6, a first capacitor C1, a boost capacitor Cboost, and a storage capacitor Cst. The first capacitor C1 includes a first plate and a second plate. The storage capacitor Cst includes a third plate Cst1 and a fourth plate Cst2. The boost capacitor Cboost includes a fifth plate and a sixth plate.

Please refer to FIG. 2, a first electrode of the switch transistor T2 is connected to a first data signal line Data1, and a second electrode of the switch transistor T2 is connected to a first node A. A switch gate T2G of the switch transistor T2 is connected to a second scan signal line Pscan1. A first electrode of the driving transistor T1 is connected to the first node A, a second electrode of the driving transistor T1 is connected to a second node B, and a drive gate T1G of the driving transistor T1 is connected to a third node Q. A first electrode of the compensation transistor T3 is connected to the third node Q, a second electrode of the compensation transistor T3 is connected to the second node B, and a compensation gate T3G of the compensation transistor T3 is connected to a first scan signal line Nscan1. A first electrode of the third reset transistor T4 is connected to a third reset signal line Vi1, a second electrode of the third reset transistor T4 is connected to the third node Q, and a third reset gate T4G of the third reset transistor T4 is connected to a third scan signal line Nscan2. A first electrode of the second reset transistor T7 is connected to a second reset signal line Vi2, a second electrode of the second reset transistor T7 is connected to an anode of the light-emitting device 211b, and a second reset gate T7G of the second reset transistor T7 is connected to a fourth scan signal line Pscan2. A first electrode of the first reset transistor T8 is connected to a first reset signal line Vi3, and a second electrode of the first reset transistor T8 is connected to the first node A. A first reset gate T8G of the first reset transistor T8 is connected to the fourth scan signal line Pscan2. A first electrode of the first light-emitting transistor T5 is connected to a first high potential line VDD1, a second electrode of the first light-emitting transistor T5 is connected to the first node A, and a first light-emitting gate T5G of the first light-emitting transistor T5 is connected to a light-emitting signal line EM. A first electrode of the second light-emitting transistor T6 is connected to the second node B, a second electrode of the second light-emitting transistor T6 is connected to the anode of the light-emitting device 211b, and a second light-emitting gate T6G of the second light-emitting transistor T6 is connected to the light-emitting signal line EM. The fifth plate of the boost capacitor Cboost is connected to the third node Q, and the sixth plate of the boost capacitor Cboost is connected to the second scan signal line Pscan1. The third plate Cst1 of the storage capacitor Cst is connected to the third node Q, and the fourth plate Cst2 of the storage capacitor Cst is connected to the first high potential line VDD1. The first plate of the first capacitor C1 is connected to the first reset signal line Vi3, and the second plate of the first capacitor C1 is connected to the first high potential line VDD1. A cathode of the light-emitting device 211b is connected to a first low potential line VSS.

It should be noted that the data signal lines connected to the switch transistors T2 in different sub-pixel units 211 are different, and the present application only takes one of them as an example for description.

In this embodiment, the first high potential line VDD1 is used to provide a constant high voltage level to the pixel driving circuit 211a, and the first low potential line VSS is used to provide a constant low voltage level to the pixel driving circuit 211a.

In this embodiment, the switch transistor T2, the driving transistor T1, the second reset transistor T7, the first reset transistor T8, the first light-emitting transistor T5, and the second light-emitting transistor T6 can be either P-type or N-type transistors. The compensation transistor T3 and the third reset transistor T4 can be of the other type, either P-type or N-type transistors. For illustrative purposes of this application, the switch transistor T2, the driving transistor T1, the second reset transistor T7, the first reset transistor T8, the first light-emitting transistor T5, and the second light-emitting transistor T6 are exemplified as P-type transistors, while the compensation transistor T3 and the third reset transistor T4 are exemplified as N-type transistors.

In the present embodiment, a capacitance value of the first capacitor C1 is less than a capacitance value of the storage capacitor Cst, and a capacitance value of the boost capacitor Cboost is also less than a capacitance value of the storage capacitor Cst. The main purpose of the storage capacitor Cst in this embodiment is to maintain the stability of the potential at the third node Q, so the capacitance of the storage capacitor Cst is relatively large. For example, the capacitance value of the storage capacitor Cst can range from 45 fF to 55 fF, while the capacitance values of the boost capacitor Cboost and the first capacitor C1 can range from 5 fF to 15 fF.

In the present embodiment, the first electrode can be either a source or a drain, and the second electrode can be the other of the source or the drain.

In the following embodiment, an angle between the first direction X and a second direction Y is greater than 0 and less than or equal to 90 degrees. For instance, the first direction X can be considered horizontal, while the second direction Y is considered vertical.

Based on the structure shown in FIG. 2, the film layer structure of the pixel driving circuit 211a in this application is described below.

Please refer to FIG. 3. The display area AA and the non-display area NA of the display panel 100 can be provided with a base substrate 110 and an array driving layer 120 disposed on the base substrate 110. Within the display area AA, the display panel 100 can also include a pixel definition layer (not illustrated) set on the array driving layer 120, a light-emitting device layer (not illustrated) arranged in the same layer as the pixel definition layer, and an encapsulation layer (not illustrated) set on the pixel definition layer. The following description mainly focuses on the film layer structure within the display area AA.

In the present embodiment, the base substrate 110 supports the various layers disposed on the base substrate 10. When the display panel 100 is a bottom-emitting or dual-emitting light-emitting display device, a transparent base substrate is used. When the display panel 100 is a top-emitting light-emitting display device, a semi-transparent or opaque base substrate, as well as a transparent base substrate, can be used.

In the present embodiment, the base substrate 110 is used to support the various film layers set on the base substrate 10. The base substrate 110 can be made of insulating materials such as glass, quartz, or polymer resin. The base substrate 110 can be either a rigid substrate or a flexible substrate that can be bent, folded, rolled, etc. Examples of flexible materials used for flexible substrates include polyimide (PI), but are not limited to polyimide (PI).

In this embodiment, the base substrate 110 can include laminated layers of a first flexible substrate 111, a first barrier layer 112, a second flexible substrate 113, and a second barrier layer 114. The first flexible substrate 111 and the second flexible substrate 113 can be made of the same material, such as polyimide. The first barrier layer 112 and the second barrier layer 114 can be formed of inorganic materials, including at least one of Silicon Oxide (SiOx) and Silicon Nitride (SiNx).

In the present embodiment, the first flexible substrate 111 is formed by applying a polymeric material to a support base (not illustrated) and then curing the polymeric material. The second flexible substrate 113 is formed by applying and curing a material that is the same as the material of the first flexible substrate 111, using the same method employed to form the first flexible substrate 111. Each of the first flexible substrate 111 and the second flexible substrate 113 can be formed with a thickness of about 8 μm to about 12 μm. Moreover, when the base substrate 110 is formed of the first flexible substrate 111 and the second flexible substrate 113, any small holes, cracks, etc., formed during the manufacturing of the first flexible substrate 111 are covered by the second flexible substrate 113, thereby eliminating such defects.

Refer to FIG. 3, the array driving layer 120 can include multiple thin-film transistors (TFTs). The TFTs can be of an etch-stop type, a back-channel etch type, or categorized based on positions of a gate and an active layer into bottom-gate TFTs, top-gate TFTs, etc. Alternatively, the TFTs can be classified based on their electrical characteristics into N-type TFTs and P-type TFTs. It's important to note that the thin-film transistors shown in FIG. 3 do not represent a structural diagram of any transistor shown in FIG. 2; instead, they are schematic representations of the various film layers of the display panel 100 in this application.

Referring to FIG. 3, the array driving layer 120 can include a light-blocking layer 121 disposed on the base substrate 110, a buffer layer 122 disposed on the light-blocking layer, a first active layer 123 disposed on the buffer layer 122, a first gate insulating layer 124 disposed on the first active layer 123, a first gate layer 125 disposed on the first gate insulating layer, a second gate insulating layer 126 disposed on the first gate layer 125, a second gate layer 127 disposed on the second gate insulating layer 126, a third gate insulating layer 128 disposed on the second gate layer 127, a second active layer 129 disposed on the third gate insulating layer 128, a fourth gate insulating layer 130 disposed on the second active layer 129, a third gate layer 131 disposed on the fourth gate insulating layer 130, a first interlayer insulating layer 132 disposed on the third gate layer 131, a first source-drain layer 133 disposed on the first interlayer insulating layer 132, a second interlayer insulating layer 134 disposed on the first source-drain layer 133, a second source-drain layer 135 disposed on the second interlayer insulating layer 134, a third interlayer insulating layer 136 disposed on the second source-drain layer 135, a third source-drain layer 137 disposed on the third interlayer insulating layer 136, and a planarization layer 138 disposed on the third source-drain layer 137.

Referring to FIG. 3, the light-blocking layer 121 is disposed on top of the second barrier layer 114. The light-blocking layer 121 is designed to prevent external light from entering the thin-film transistors from the bottom. The light-blocking layer 121 can be made of black light-blocking materials, such as black light-blocking metals or black organic materials, etc.

Referring again to FIG. 3, the buffer layer 122 is placed on top of the light-blocking layer 121. The buffer layer 122 serves to isolate the light-blocking layer 121 from the upper metal materials. A material for the buffer layer 122 can include compounds made up of nitrogen, silicon, and oxygen, such as a single layer of silicon oxide film, or a stacked structure of silicon oxide-silicon nitride.

Referring to FIG. 3, the first active layer 123 is positioned on top of the buffer layer 122, and the second active layer 129 can be positioned on top of the third gate insulating layer 128. Materials for the first active layer 123 and the second active layer 129 can be indium gallium zinc oxide (IGZO) semiconductor, amorphous silicon, or low-temperature polysilicon. For instance, in the present application, the material for the first active layer 123 can be low-temperature polysilicon, and the material for the second active layer 129 can be indium gallium zinc oxide semiconductor.

Referring to FIG. 3, the first gate insulating layer 124, the second gate insulating layer 126, the third gate insulating layer 128, the fourth gate insulating layer 130, the first interlayer insulating layer 132, the second interlayer insulating layer 134, and the third interlayer insulating layer 136 are each positioned on their corresponding metal or semiconductor layers, separating different layers of metal or semiconductor. The materials for the first gate insulating layer 124, the second gate insulating layer 126, the first interlayer insulating layer 132, the third gate insulating layer 128, the fourth gate insulating layer 130, the second interlayer insulating layer 134, and the third interlayer insulating layer 136 can be inorganic compounds composed of silicon nitride or organics with planarization properties.

Referring to FIG. 3, the first gate layer 125, the second gate layer 127, and the third gate layer 131 are each positioned on their corresponding insulating layers. Materials for the first gate layer 125, the second gate layer 127, and the third gate layer 131 can be copper, molybdenum, or molybdenum-titanium alloy, etc.

Referring again to FIG. 3, the first source-drain layer 133 is positioned on the first interlayer insulating layer 132, the second source-drain layer 135 is positioned on the second interlayer insulating layer 134, and the third source-drain layer 137 is positioned on the third interlayer insulating layer 136. Materials for the first source-drain layer 133, the second source-drain layer 135, and the third source-drain layer 137 can be copper, molybdenum, molybdenum-titanium alloy, or a titanium-aluminum-titanium tri-layer metal, etc.

Referring to FIG. 3, the planarization layer 138 is laid out across the entire layer to ensure the flatness of the film layers within the array driving layer 120. A material for the planarization layer 138 can be inorganic compounds composed of silicon nitride or organics with planarization properties.

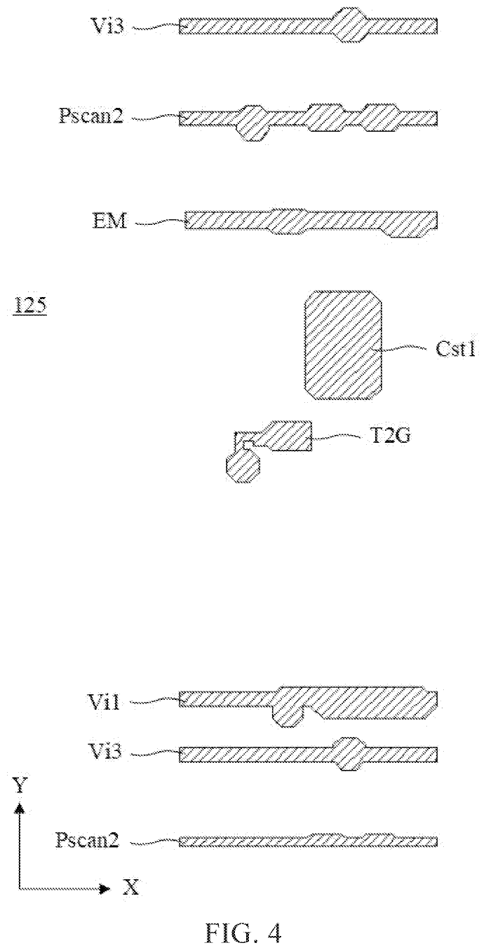

Referring to FIG. 4, the first gate layer 125 includes the light-emitting signal line EM, the third reset signal line Vi1, the first reset signal line Vi3, and the fourth scan signal line Pscan2. The light-emitting signal line EM, the third reset signal line Vi1, the first reset signal line Vi3, and the fourth scan signal line Pscan2 all extend in the first direction X, and the first reset signal line Vi3, the fourth scan signal line Pscan2, the light-emitting signal line EM, and the third reset signal line Vi1 are arranged at intervals along the second direction Y.

Refer to FIG. 4, the first gate layer 125 also includes the switch gate T2G and the third plate Cst1 of the storage capacitor Cst, which are positioned between the light-emitting signal line EM and the third reset signal line Vi1. The switch gate T2G and the third plate Cstl are arranged at intervals along the second direction Y, with the third plate Cst1 closer to the light-emitting signal line EM, and the switch gate T2G set farther away from the light-emitting signal line EM.

In this embodiment, the light-emitting signal line EM can directly serve as both the first light-emitting gate T5G and the second light-emitting gate T6G, while the fourth scan signal line Pscan2 can directly act as both the second reset gate T7G and the first reset gate T8G.

Referring to FIG. 4, the shapes of the switch gate T2G and the third plate Cst can be rectangular, and all four corners of the third plate Cst1 can be chamfered.

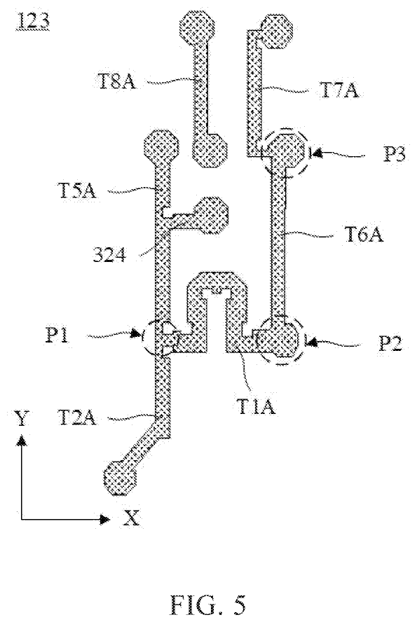

Referring to FIG. 5, the first active layer 123 includes a switch active part T2A of the switch transistor T2, a drive active part T1A of the driving transistor T1, a second reset active part T7A of the second reset transistor T7, a first reset active part T8A of the first reset transistor T8, a first light-emitting active part T5A of the first light-emitting transistor T5, and a second light-emitting active part T6A of the second light-emitting transistor T6.

Referring to FIG. 5, the switch active part T2A, the drive active part T1A, the second reset active part T7A, the first light-emitting active part T5A, and the second light-emitting active part T6A are interconnected, while the first reset active part T8A is set apart from the other active parts. The switch active part T2A, the second reset active part T7A, the first reset active part T8A, the first light-emitting active part T5A, and the second light-emitting active part T6A are all elongated and extend along the second direction Y. The drive active part T1A has a hook shape and is positioned between the first light-emitting active part T5A and the second light-emitting active part T6A. A first end of the switch active part T2A, a first end of the drive active part T1A, and a first end of the first light-emitting active part T5A are connected at a first connection point P1. A second end of the drive active part T1A and a first end of the second light-emitting active part T6A are connected at a second connection point P2. A first end of the second reset active part T7A and a second end of the second light-emitting active part T6A are connected at a third connection point P3.

In the present embodiment, the first connection point P1 serves as the first node A, the second connection point P2 serves as the second node B, and the third node Q is the point where the anode of the light-emitting device 211b is located.

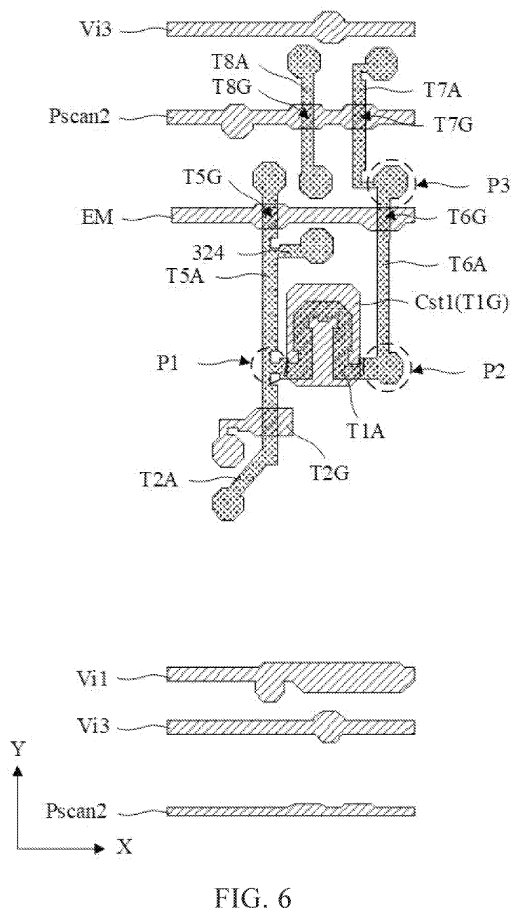

Referring to FIG. 6, the light-emitting signal line EM partially overlaps with the first light-emitting active part T5A, and this overlapping portion serves as a channel of the first light-emitting active part T5A. The light-emitting signal line EM partially overlaps with the second light-emitting active part T6A, and this overlapping portion serves as a channel of the second light-emitting active part T6A. The switch gate T2G partially overlaps with the switch active part T2A, and this overlapping portion serves as a channel of the switch active part T2A. The fourth scan signal line Pscan2 partially overlaps with the second reset active part T7A, and this overlapping portion serves as a channel of the second reset active part T7A. The fourth scan signal line Pscan2 also partially overlaps with the first reset active part T8A, and this overlapping portion serves as a channel of the first reset active part T8A. The drive active part T1A partially overlaps with the third plate Cst1, and this overlapping portion serves as a channel of the drive active part T1A. In this application, the third plate Cst1 is repurposed as the drive gate T1G for the driving transistor T1.

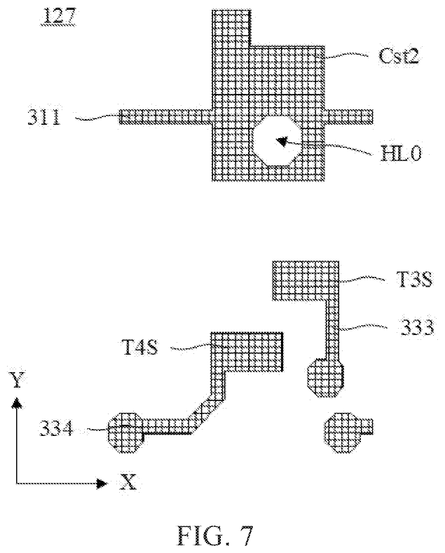

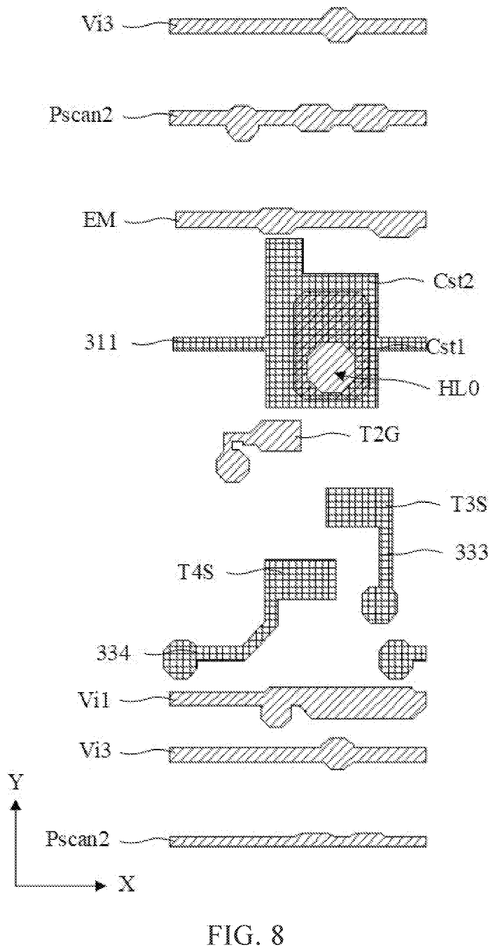

Referring to FIGS. 7 and 8, the second gate layer 127 includes the fourth plate Cst2 of the storage capacitor Cst, a first shading unit T3S of the compensation transistor T3, and a second shading unit T4S of the third reset transistor T4, arranged along the second direction Y. The fourth plate Cst2, the first shading unit T3S, and the second shading unit T4S are positioned between the light-emitting signal line EM and the third reset signal line Vi1. The third plate Cst1 is disposed close to the light-emitting signal line EM, the second shading unit T4S is disposed close to the third reset signal line Vi1, and the first shading unit T3S is located between the second shading unit T4S and the fourth plate Cst2.

Referring to FIGS. 7 and 8, an area of the fourth plate Cst2 is greater than an area of the third plate Cst1. Moreover, an orthographic projection of the third plate Cst1 projected on the fourth plate Cst2 falls within the fourth plate Cst2. A first via hole HLO is created in the fourth plate Cst2 to expose a portion of the third plate Cst1.

Referring to FIG. 8, shapes of the first shading unit T3S, the second shading unit T4S, and the fourth plate Cst2 can be rectangular, and at least some of their corners can be chamfered.

Referring to FIG. 8, the second gate layer 127 also includes first electrical connection segments 311 arranged on two sides of the fourth plate Cst2. Both of these first electrical connection segments 311 extend along the first direction X, and in two adjacent sub-pixel units 211 arranged along the first direction X, the fourth plates Cst2 of the two sub-pixel units 211 are electrically connected through the first electrical connection segments 311. In this embodiment, the fourth plate Cst2 is connected to the first high potential line VDD1. To reduce the impedance on the fourth plate Cst2, this application can connect the fourth plates Cst2 of the sub-pixel units 211 arranged along the first direction X to each other and parallel them with the upper first high potential line VDD1, thereby lowering the impedance of the first high potential line VDD1 and the fourth plate Cst2.

Referring to FIGS. 9 and 11, the second active layer 129 includes a compensation active part T3A of the compensation transistor T3 and a third reset active part T4A of the third reset transistor T4. Both the compensation active part T3A and the third reset active part T4A extend along the second direction Y. A first end of the compensation active part T3A and a first end of the third reset active part T4A are connected at a fourth connection point P4. A second end of the compensation active part T3A extends towards the second connection point P2 and is set apart from the second connection point P2, while a second end of the third reset active part T4A extends towards and overlaps with the third reset signal line Vi1.

In the present embodiment, the fourth connection point P4 can serve as the third node Q.

Referring to FIGS. 9 and 11, the second active layer 129 also includes a first extension segment 321 connected to the fourth connection point P4 and a second extension segment 322 connected to the second end of the third reset active part T4A. The first extension segment 321 extends along the second direction Y towards the location of the storage capacitor Cst and is set apart from the storage capacitor Cst. The second extension segment 322 extends along the first direction X and overlaps at least partially with the third reset signal line Vi1.

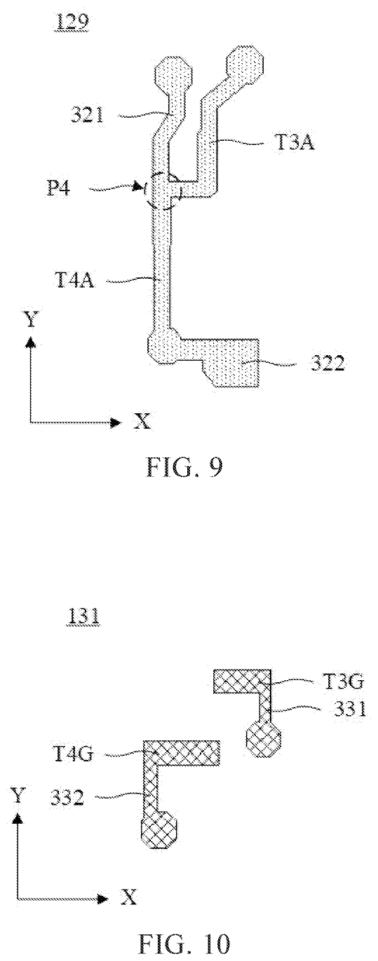

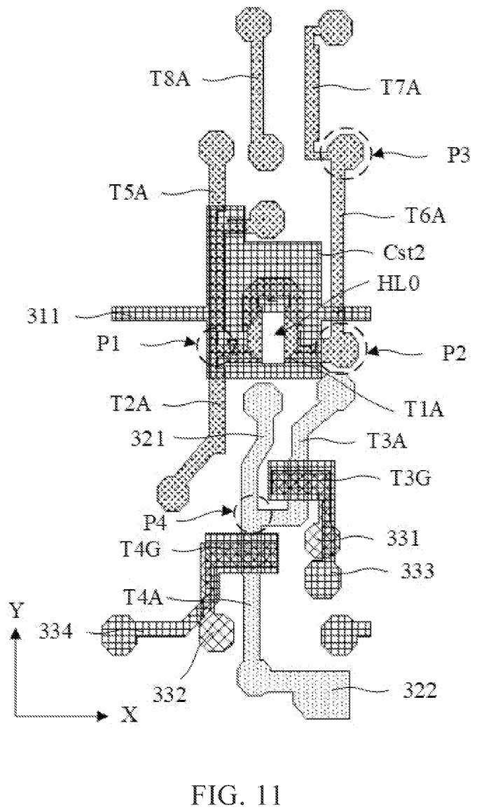

Referring to FIGS. 10 and 11, the third gate layer 131 includes the compensation gate T3G and the third reset gate T4G of the third reset transistor T4. An area of the compensation gate T3G is smaller than an area of the first shading unit T3S, and an orthographic projection of the compensation gate T3G projected on the first shading unit T3S falls within the first shading unit T3S. Similarly, an area of the third reset gate T4G is smaller than an area of the second shading unit T4S, and an orthographic projection of the third reset gate T4G projected on the second shading unit T4S falls within the second shading unit T4S.

Referring to FIGS. 10 and 11, the third reset gate T4G partially overlaps with the third reset active part T4A, and this overlapping portion serves as a channel of the third reset active part T4A. The compensation gate T3G partially overlaps with the compensation active part T3A, and this overlapping portion serves as a channel of the compensation active part T3A.

Referring to FIGS. 10 and 11, both the third reset gate T4G and the compensation gate T3G can have a rectangular shape, and some of the corners of the third reset gate T4G and the compensation gate T3G can be chamfered.

Referring to FIGS. 10 and 11, the third gate layer 131 also includes a first conductive segment 331 connected to the compensation gate T3G, and a second conductive segment 332 connected to the third reset gate T4G. The first conductive segment 331 extends along the second direction Y and towards a side away from the compensation gate T3G. Similarly, the second conductive segment 332 extends along the second direction Y and towards a side away from the third reset gate T4G.

Referring to FIGS. 7 and 11, the second gate layer 127 also includes a third conductive segment 333 connected to the first shading unit T3S, and a fourth conductive segment 334 connected to the second shading unit T4S. The third conductive segment 333 extends along the second direction Y and towards a side away from the compensation gate T3G. A linewidth of the first conductive segment 331 can be less than or equal to a linewidth of the third conductive segment 333, and an orthographic projection of the first conductive segment 331 projected on the third conductive segment 333 can fall within the third conductive segment 333. The fourth conductive segment 334 can first extend along the second direction Y and towards a side away from the third reset gate T4G, and then extend along the first direction X and towards a side away from the compensation transistor T3. The ends of the second conductive segment 332 and the fourth conductive segment 334 that are away from the third reset gate T4G can be located on the same horizontal line.

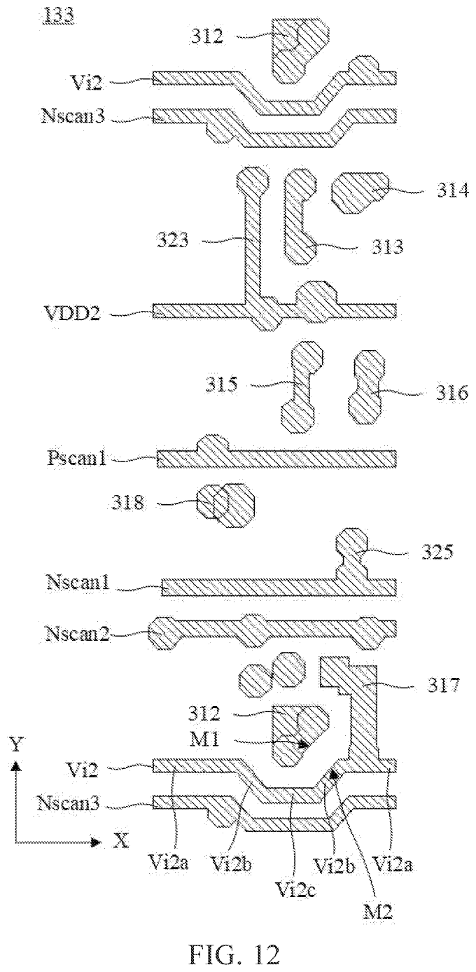

Referring to FIG. 12, the first source-drain layer 133 includes the second reset signal line Vi2, a fifth scan signal line Nscan3, a second high potential line VDD2, the second scan signal line Pscan1, the first scan signal line Nscan1, and the third scan signal line Nscan2, arranged along the second direction Y. The second reset signal line Vi2, the fifth scan signal line Nscan3, the second high potential line VDD2, the second scan signal line Pscan1, the first scan signal line Nscan1, and the third scan signal line Nscan2 can all extend along the first direction X.

Referring to FIGS. 12 to 15, the second reset signal line Vi2 is positioned between the first reset signal line Vi3 and the first scan signal line Nscan1. The fifth scan signal line Nscan3 partially overlaps with the fourth scan signal line Pscan2. The second high potential line VDD2 is placed between the light-emitting signal line EM and the first electrical connection segment 311. The second scan signal line Pscan1, the first scan signal line Nscan1, and the third scan signal line Nscan2 are located between the first electrical connection segment 311 and the third reset signal line Vi1. The second scan signal line Pscan1 is disposed close to the first electrical connection segment 311, the third scan signal line Nscan2 is disposed close to the third reset signal line Vi1, and the first scan signal line Nscan1 is positioned between the second scan signal line Pscan1 and the third scan signal line Nscan2.

Refer to FIGS. 12 to 15, the first source-drain layer 133 also includes a second electrical connection segment 312 positioned between the second reset signal line Vi2 and the first reset signal line Vi3. A first end of the second electrical connection segment 312 is electrically connected to the first reset signal line Vi3 through a first via hole HL1, and a second end of the second electrical connection segment 312 is electrically connected to a first end of the first reset active part T8A through a second via hole HL2. The first reset signal line Vi3 transfers the reference voltage to the first reset transistor T8 via the second electrical connection segment 312.

In this embodiment, the first via hole HL1 penetrates the second gate insulating layer 126, the third gate insulating layer 128, the fourth gate insulating layer 130, and the first interlayer insulating layer 132. The second via hole HL2 penetrates the first gate insulating layer 124, the second gate insulating layer 126, the third gate insulating layer 128, the fourth gate insulating layer 130, and the first interlayer insulating layer 132.

Referring to FIGS. 12 to 15, the first source-drain layer 133 also includes a third extension segment 323, a third electrical connection segment 313, and a fourth electrical connection segment 314, which are positioned between the second high potential line VDD2 and the fifth scan signal line Nscan3. Both the third extension segment 323 and the third electrical connection segment 313 extend along the second direction Y, while the fourth electrical connection segment 314 extends along the first direction X.

In this embodiment, a first end of the third extension segment 323 is electrically connected to the second high potential line VDD2, and a second end of the third extension segment 323 extends towards a side away from the second high potential line VDD2. Additionally, the third extension segment 323 overlaps partially with the first light-emitting active part T5A, and the second end of the third extension segment 323 is electrically connected to a second end of the first light-emitting active part T5A through the third via hole HL3. A first end of the third electrical connection segment 313 electrically connects to a second end of the first reset active part T8A through a fourth via hole HL4. The first active layer 123 also includes a fourth extension segment 324 linked to the first light-emitting active part T5A, which extends along the first direction X. A second end of the third electrical connection segment 313 is electrically connected to the fourth extension segment 324 through a fifth via hole HL5. The first reset signal line Vi3 transfers the reference voltage to the first connection point P1 through the second electrical connection segment 312, the third electrical connection segment 313, and the fourth extension segment 324 to reset the potential of the first node A. One end of the fourth electrical connection segment 314 is electrically connected to the third connection point P3 in the first active layer 123 through a via hole, and another end of the fourth electrical connection segment 314 is electrically connected to a conductive layer in the second source-drain layer 135 through another via hole.

In the present embodiment, the third via hole HL3 penetrates the first gate insulating layer 124, the second gate insulating layer 126, the third gate insulating layer 128, the fourth gate insulating layer 130, and the first interlayer insulating layer 132. Both the fourth via hole HL4 and the fifth via hole HL5 penetrate through the first gate insulating layer 124, the second gate insulating layer 126, the third gate insulating layer 128, the fourth gate insulating layer 130, and the first interlayer insulating layer 132.

Referring to FIGS. 12 to 15, the first source-drain layer 133 further includes a fifth electrical connection segment 315 and a sixth electrical connection segment 316, which are positioned between the second high potential line VDD2 and the second scan signal line Pscan1. Both the fifth electrical connection segment 315 and the sixth electrical connection segment 316 extend along the second direction Y.

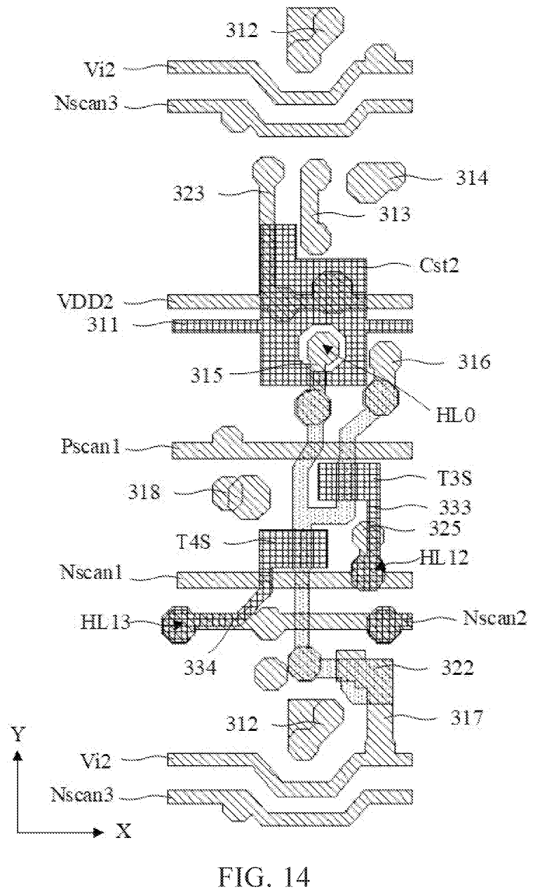

In the present embodiment, a first end of the fifth electrical connection segment 315 is electrically connected through a sixth via hole HL6 to an end of the first extension segment 321 that is away from the second scan signal line Pscan1. A second end of the fifth electrical connection segment 315 extends into the storage capacitor Cst and electrically connects to the third plate Cst1 of the storage capacitor Cst through a seventh via hole HL7. In the structure shown in FIG. 14, the seventh via hole HL7 passes through the first via hole HLO located on the fourth plate Cst2. A center of the first via hole HLO and a center of the seventh via hole HL7 can be on a same line perpendicular to the light-emitting surface of the display panel 100. A first end of the sixth electrical connection segment 316 electrically connects through an eighth via hole HL8 to the second connection point P2 in the first active layer 123. A second end of the sixth electrical connection segment 316 electrically connects through a ninth via hole HL9 to the second end of the compensation active part T3A.

In the present embodiment, the sixth via hole HL6 and the ninth via hole HL9 penetrate through the fourth gate insulating layer 130 and the first interlayer insulating layer 132. The seventh via hole HL7 and the eighth via hole HL8 penetrate through the first gate insulating layer 124, the second gate insulating layer 126, the third gate insulating layer 128, the fourth gate insulating layer 130, and the first interlayer insulating layer 132.

Referring to FIGS. 12 to 15, the first source-drain layer 133 also includes a fifth extension segment 325. One end of the fifth extension segment 325 is electrically connected to the first scan signal line Nscan1. The fifth extension segment 325 extends along the second direction Y and towards one side away from the first scan signal line Nscan1. An end of the fifth extension segment 325 that is away from the first scan signal line Nscan1 electrically connects through a tenth via hole HL10 to the first conductive segment 331. The first scan signal line Nscan1 transmits a scan signal to the compensation gate T3G of the compensation transistor T3 through the fifth extension segment 325 and the first conductive segment 331. At the same time, an end of the second conductive segment 332 that is away from the third reset gate T4G overlaps with the third scan signal line Nscan2, and electrically connects through an eleventh via hole HL11 to the third scan signal line Nscan2. The third scan signal line Nscan2 transmits a scan signal to the third reset gate T4G of the third reset transistor T4 through the second conductive segment 332.

In the present embodiment, both the tenth via hole HL10 and the eleventh via hole HL11 penetrate through the first interlayer insulating layer 132.

Referring to FIGS. 12 to 15, the third conductive segment 333 overlaps with both the first conductive segment 331 and the third conductive segment 333, and electrically connects to the first scan signal line Nscan1 through a twelfth via hole HL12. The first scan signal line Nscan1 transmits a scan signal to the first shading unit T3S via the third conductive segment 333. Hence, the first shading unit T3S can be repurposed as a bottom gate of the compensation transistor T3, with the compensation gate T3G serving as a top gate of the compensation transistor T3. The arrangement of the first shading unit T3S and the compensation gate T3G can increase the conduction rate of the compensation transistor T3, enhancing the device effect of the compensation transistor T3. The fourth conductive segment 334 overlaps with a portion of the third scan signal line Nscan2 and electrically connects through a thirteenth via hole HL13 to the third scan signal line Nscan2. The third scan signal line Nscan2 transmits a scan signal to the second shading unit T4S via the fourth conductive segment 334. Therefore, the second shading unit T4S can be repurposed as a bottom gate of the third reset transistor T4, with the third reset gate T4G serving as a top gate of the third reset transistor T4. The arrangement of the second shading unit T4S and the third reset gate T4G can increase the conduction rate of the third reset transistor T4, enhancing the device effect of the third reset transistor T4.

In the present embodiment, both the twelfth via hole HL12 and the thirteenth via hole HL13 penetrate through the third gate insulating layer 128, the fourth gate insulating layer 130, and the first interlayer insulating layer 132.

It should be noted that the third conductive segment 333 can be electrically insulated from the first scan signal line Nscan1, and the fourth conductive segment 334 can be electrically insulated from the third scan signal line Nscan2.

As shown in FIGS. 12 to 15, the fifth scan signal line Nscan3 is connected in parallel with the fourth scan signal line Pscan2 through a fourteenth via hole HL14. This parallel configuration of the fifth scan signal line Nscan3 and the fourth scan signal line Pscan2 is designed to reduce the impedance of both scan signal lines.

Furthermore, in this embodiment, the fourteenth via hole HL14 penetrates the second gate insulating layer 126, the third gate insulating layer 128, the fourth gate insulating layer 130, and the first interlayer insulating layer 132.

Referring to FIGS. 12 to 15, the first scan signal line Nscan1 partially overlaps with the third reset active part T4A, the second scan signal line Pscan1 partially overlaps with the first extension segment 321, and the second scan signal line Pscan1 partially overlaps with the compensation active part T3A. The third scan signal line Nscan2 partially overlaps with the third reset active part T4A. These four overlapping areas all involve the material of the second active layer 129 overlapping with the material of the first source-drain layer 133, with the fourth gate insulating layer 130 and the first interlayer insulating layer 132 separating the first source-drain layer 133 from the second active layer 129. No material from the third gate layer 131 is placed in between the first source-drain layer 133 and the second active layer 129, avoiding the technical issue of potential short circuits between the third gate layer 131 and the first source-drain layer 133.

Referring to FIGS. 12 to 15, the portion where the second scan signal line Pscan1 overlaps with the first extension segment 321 constitutes the boost capacitor Cboost of this application. The fifth plate of the boost capacitor Cboost can be the part of the first extension segment 321 that overlaps with the second scan signal line Pscan1, and the sixth plate of the boost capacitor Cboost can be the part of the second scan signal line Pscan1 that overlaps with the first extension segment 321.

Referring to FIGS. 12 to 15, the first source-drain layer 133 also includes a seventh electrical connection segment 317 positioned between the second reset signal line Vi2 and the third scan signal line Nscan2. The seventh electrical connection segment 317 extends along the second direction Y and towards a side away from the second reset signal line Vi2. The seventh electrical connection segment 317 overlaps with the second extension segment 322, effectively forming a capacitor between the third reset signal line Vi1 and the second reset signal line Vi2, ensuring the stability of the voltage on the third reset signal line Vi1 and the second reset signal line Vi2.

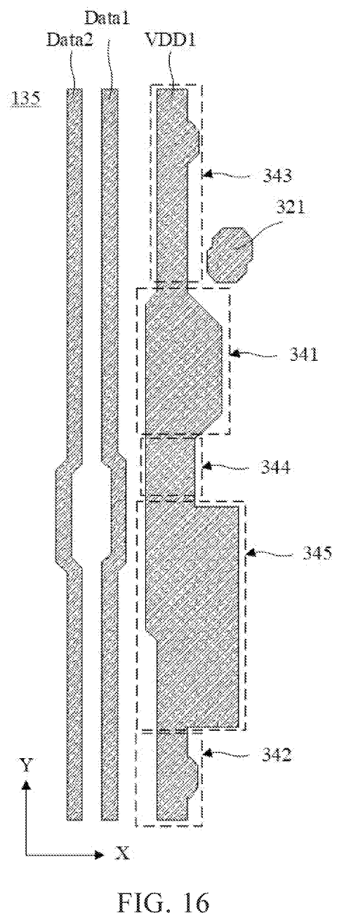

Referring to FIG. 16, the second source-drain layer 135 includes the first data signal line Data1, the second data signal line Data2, and the first high potential line VDD1. The second data signal line Data2, the first data signal line Data1, and the first high potential line VDD1 are arranged in sequence along the first direction X and extend along the second direction Y. The first data signal line Datal is positioned between the second data signal line Data2 and the first high potential line VDD1.

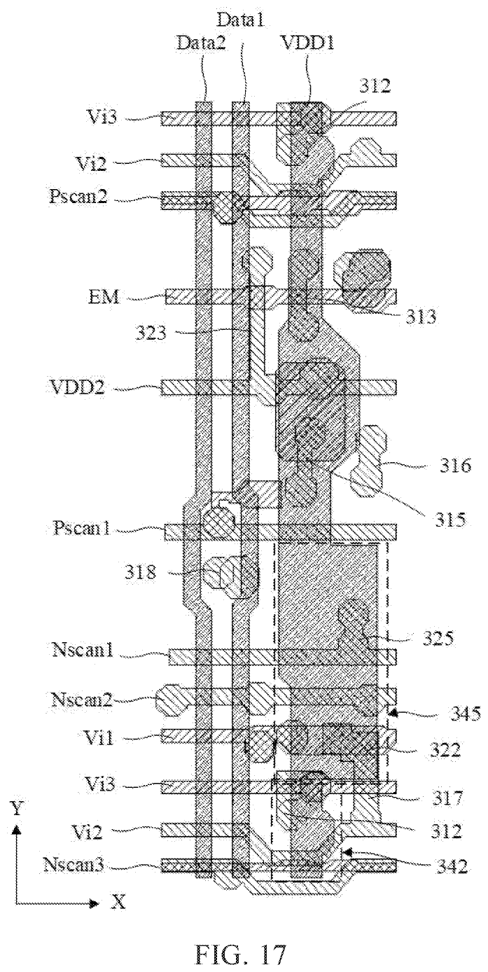

Referring to FIGS. 17 to 19, the first source-drain layer 133 includes an eighth electrical connection segment 318 positioned between the first scan signal line Nscan1 and the second scan signal line Pscan1. One end of the eighth electrical connection segment 318 is electrically connected to a second end of the switch active part T2A, and another end of the eighth electrical connection segment 318 is electrically connected to the first data signal line Data1. The first data signal line Datal transmits a data signal to the switch transistor T2 through the eighth electrical connection segment 318.

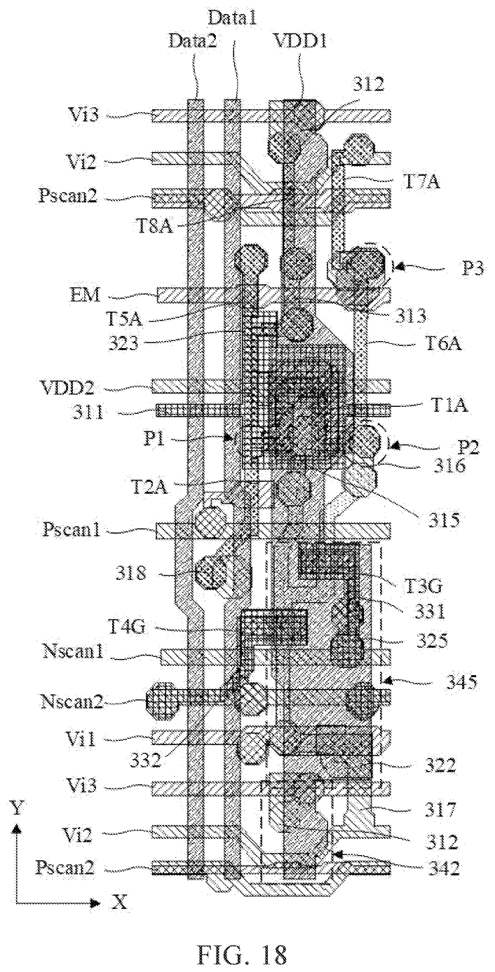

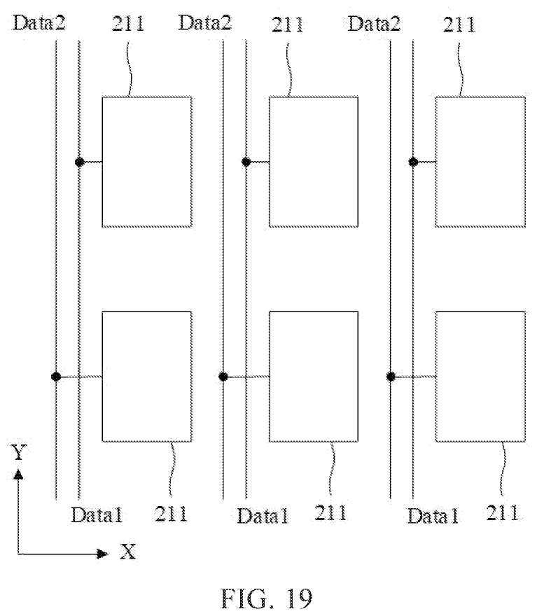

In the structure shown in FIG. 19, the present application shows 6 sub-pixel units 211 as an example. The sub-pixel units 211 located in the first row are all connected to the first data signal line Data1, while the sub-pixel units 211 located in the second row are all connected to the second data signal line Data2. The sub-pixel units 211 shown in FIGS. 17 and 18 correspond to the sub-pixel units 211 in the first row of FIG. 19.

In the present embodiment, each pixel driving circuit 211a has the same structure, meaning that an input end of the switch active part T2A of the switch transistor T2 is positioned on the same side for all. If the first data signal line Datal and the second data signal line Data2 are placed on opposite sides of the pixel driving circuit 211a, such as, for example, when the first data signal line Datal is on the left side of the pixel driving circuit 211a and the second data signal line Data2 is on the right side of the pixel driving circuit 211a, then the input end of the switch active part T2A of each sub-pixel unit 211 in the first row would be adjacent to the first data signal line Data1. Meanwhile, a distance between the switch active part T2A of the sub-pixel unit 211 in the second row and the corresponding second data signal line Data2 is a width of one sub-pixel unit 211. This configuration requires a connection line that spans across the sub-pixel unit 211 to electrically connect the second data signal line Data2 with the switch active part T2A of the sub-pixel unit 211 in the second row. The connection line, overlapping with multiple structures within the pixel driving circuit 211a, increases the coupling capacitance, leading to decreased stability of the pixel driving circuit 211a. Referring to FIG. 19, by placing both data signal lines on the same side of the pixel driving circuit 211a, this application reduces the distance between the data signal line and the switch active part T2A of the sub-pixel unit 211. This arrangement decreases the internal coupling capacitance within the pixel driving circuit 211a, thereby enhancing the stability of the pixel driving circuit 211a.

Referring to FIGS. 16 to 18, the first high potential line VDD1 includes a first sub-plate 341, a second sub-plate 342, a third sub-plate 343, a fourth sub-plate 344, and a fifth sub-plate 345. The third sub-plate 343, the first sub-plate 341, the fourth sub-plate 344, the fifth sub-plate 345, and the second sub-plate 342 are arranged along the second direction Y. The first sub-plate 341 is positioned between the third sub-plate 343 and the fourth sub-plate 344, the fourth sub-plate 344 is located between the third sub-plate 343 and the fifth sub-plate 345, and the second sub-plate 342 is positioned on a side of the fifth sub-plate 345 that is away from the fourth sub-plate 344. In the first direction X, a width of the first sub-plate 341 is less than a width of the fifth sub-plate 345. The width of the first sub-plate 341 can be greater than a width of the fourth sub-plate 344, and the width of the fourth sub-plate 344 can be greater than or equal to widths of the third sub-plate 343 and the second sub-plate 342.

In the present embodiment, since the potential of the drive gate T1G is the potential of the third node Q, and changes in the potential of the third node Q directly affect the operating current of the light-emitting device 211b, it is necessary to ensure the stability of the potential of the third node Q. The present application can achieve this by ensuring that an orthographic projection of the drive gate T1G on the first high potential line VDD1 falls within the first sub-plate 341, thereby effectively using the first sub-plate 341 as a shielding layer to maintain the stability of the potential of the third node Q. Therefore, it is necessary to increase the lateral width of the first sub-plate 341 to fully cover the drive gate T1G. The third plate Cstl of the storage capacitor Cst is repurposed as the drive gate T1G, meaning that an orthographic projection of the third plate Cst1 projected on the first high potential line VDD1 can fall within the first sub-plate 341. Thus, the width of the first sub-plate 341 in this application can be greater than the widths of the third sub-plate 343, the fourth sub-plate 344, and the second sub-plate 342.

In the present embodiment, since both the fifth electrical connection segment 315 and the first extension segment 321 are electrically connected to the drive gate TIG, changes in the potential on the fifth electrical connection segment 315 and the first extension segment 321 also affect the potential of the drive gate T1G. Therefore, this application can increase the width of the fourth sub-plate 344 to fully cover both the fifth electrical connection segment 315 and the first extension segment 321. As a result, the lateral width of the fourth sub-plate 344 in this application can be greater than the lateral widths of both the third sub-plate 343 and the second sub-plate 342.

Referring to FIGS. 12, 17, and 18, the second electrical connection segment 312 can serve as a first sub-part of the first plate, with one end of the first sub-part electrically connected to the first reset signal line Vi3, and another end of the first sub-part connected to an active part of the first reset transistor T8. An orthographic projection of the first sub-part projected on the second source-drain layer 135 is at least partially located within the first high potential line VDD1. Furthermore, the second sub-plate 342 can act as a second plate of the first capacitor C1.

The present application achieves stability in the reset signal transmitted by the first reset signal line Vi3 by overlapping the second electrical connection segment 312 with a part of the first high potential line VDD1, where the second electrical connection segment 312 acts as the first plate and the second sub-plate 342 acts as the second plate, the first plate and the second plate together forming the first capacitor C1. The constant high potential on the second plate enhances the anti-coupling capability of the first reset signal line Vi3, thereby increasing the stability of the reset signal it carries. This prevents abnormal output voltage at the output end of the first reset transistor T8, ensuring that the voltage at the reset node between the switch transistor T2 and the first reset transistor T8 is reset to the reference voltage, addressing the technical issue of display anomalies in display panel 100.

Referring to FIGS. 12, 17, and 18, the second electrical connection segment 312 can be shaped as a right-angled triangle, with the locations of its two acute angles corresponding to the positions of the first via hole HL1 and the second via hole HL2. In existing technology, the second electrical connection segment 312 only needs to extend along the straight line segment between the first via hole HL1 and the second via hole HL2. However, by designing the second electrical connection segment 312 as a right-angled triangle, overlapping the second electrical connection segment 312 with a part of the first reset signal line Vi3, and separating the second electrical connection segment 312 from the second reset signal line Vi2, this application increases both a longitudinal width and a lateral width of the second electrical connection segment 312, thus essentially enlarging an area of the second electrical connection segment 312. Consequently, this increases an overlapping area between the second electrical connection segment 312 and the first high potential line VDD1, which in turn increases the capacitance of the first capacitor C1, further enhancing the stability of the reset signal transmitted by the first reset signal line Vi3.

In the present embodiment, to avoid interference between the second electrical connection segment 312 and the second reset signal line Vi2, the second reset signal line Vi2 is designed to be recessed at a position corresponding to the second electrical connection segment 312, meaning that the signal line in this area shifts away from the first reset signal line Vi3. At the same time, to maintain a spacing between the fifth scan signal line Nscan3 and the second reset signal line Vi2, the fifth scan signal line Nscan3 is also designed to be recessed.

Referring to FIGS. 12, 17, and 18, the second reset signal line Vi2 includes a horizontal segment Vi2a, inclined segments Vi2b, and a bypass segment Vi2c. Each of two ends of the bypass segment Vi2c is connected to one inclined segment Vi2b, where one end of the inclined segment Vi2b, which is away from the bypass segment Vi2c, connects to the horizontal segment Vi2a. A distance between the horizontal segment Vi2a and the first reset signal line Vi3 is smaller than a distance between the bypass segment Vi2c and the second reset signal line Vi2. The bypass segment Vi2c is positioned directly corresponding to the first sub-part. In this application, a distance by which the bypass segment Vi2c is recessed relative to the second reset signal line Vi2 can be set based on a vertical distance between the horizontal segment Vi2a and the first reset signal line Vi3. For example, a vertical distance between the second via hole HL2 in the second electrical connection segment 312 and the bypass segment Vi2c, and a vertical distance between the horizontal segment Vi2a and the first reset signal line Vi3, can be made approximately equal.

Referring to FIGS. 12, 17, and 18, the first sub-part includes a first inclined surface M1 facing towards the second reset signal line Vi2. The inclined segment Vi2b includes a second inclined surface M2 facing towards the first sub-part. The first inclined surface M1 and the second inclined surface M2 are parallel. By aligning the first inclined surface M1 of the second electrical connection segment 312 and the second inclined surface M2 of the inclined segment Vi2b in parallel, a distance between the second electrical connection segment 312 and the inclined segment Vi2b is kept uniform. With the second reset signal line Vi2 and the second electrical connection segment 312 electrically insulated from each other, this arrangement achieves a compact layout of the film structure.

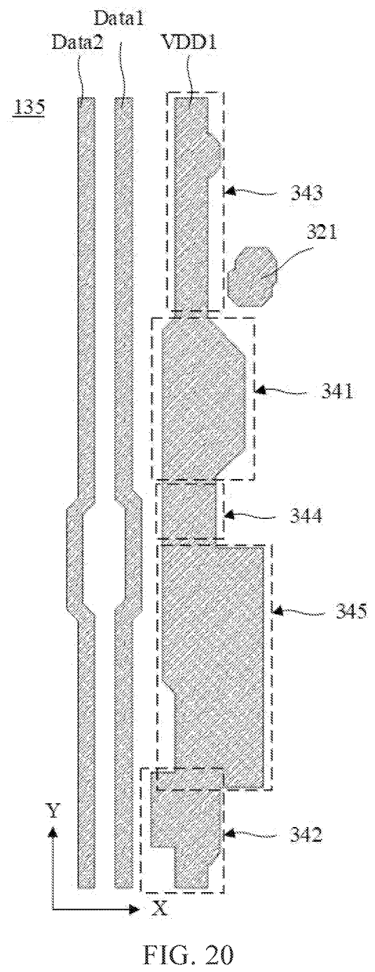

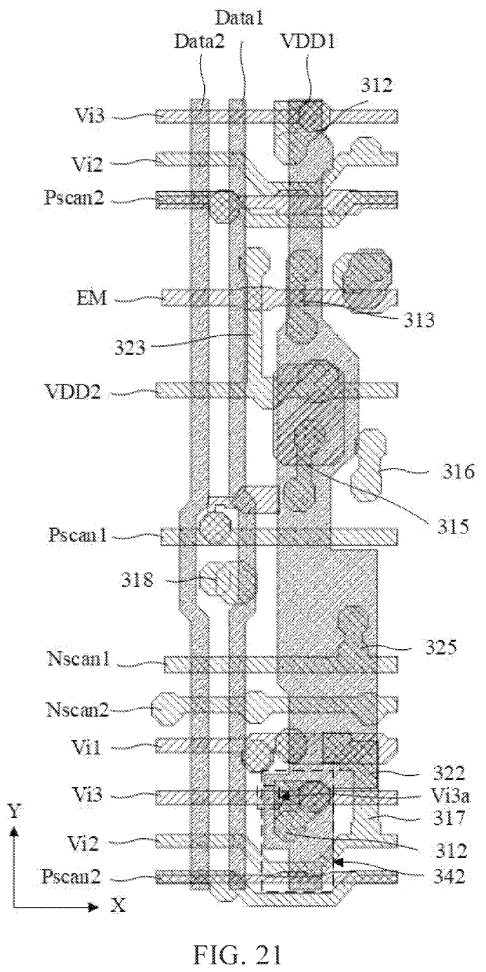

Referring to FIGS. 20 and 21, in comparison to the structure shown in FIG. 16, this application can increase the width of the second sub-plate 342 within the first high potential line VDD1, ensuring that the second electrical connection segment 312 on the first high potential line VDD1 is located within the second sub-plate 342. Increasing the lateral width of the second sub-plate 342 effectively enlarges an overlapping area between the second sub-plate 342 and the second electrical connection segment 312, thereby increasing the capacitance of the first capacitor C1. This enhancement in the capacitance of the first capacitor C1 improves the anti-coupling capability of the first reset signal line Vi3, further stabilizing the reset signal transmitted by the first reset signal line Vi3.

In this embodiment, the increase in the lateral width of the second sub-plate 342 brings it closer to the first data signal line Data1, resulting in a distance between the first sub-plate 341 and the first data signal line Datal being greater than a distance between the second sub-plate 342 and the first data signal line Data1.

Refer to FIG. 21, a portion of the first reset signal line Vi3 is repurposed as a second sub-part Vi3a of the first plate. An orthographic projection of the second sub-part Vi3a projected on the first source-drain layer 133 does not overlap with the first sub-part, and an orthographic projection of the second sub-part Vi3a projected on the second source-drain layer 135 is located within the first high potential line VDD1. The increase in the lateral width of the second sub-plate 342 causes it to overlap with a part of the first reset signal line Vi3, and this part of the first reset signal line Vi3 serves as the second sub-plate 342 of the first plate, effectively increasing an area of the first plate. This, in turn, enhances a relative area between the first plate and the second plate, increasing the capacitance of the first capacitor C1 and thereby improving the anti-coupling capability of the first reset signal line Vi3.

It should be noted that in existing technology, there is a relatively small overlapping area between the first reset signal line Vi3 and the first high potential line VDD1, resulting in that a first capacitance value for the first capacitor C1 can be 7.3 fF, while a second capacitance value between the data line and the first reset signal line Vi3 is 0.68 fF. Taking the second source-drain layer 135 in FIGS. 16 to 18 as an example, the first capacitance value of the first capacitor C1 between the first high potential line VDD1 and the first reset signal line Vi3 increases to 18.5 fF, whereas the second capacitance value between the data line and the first reset signal line Vi3 remains at 0.68 fF. Therefore, compared to existing technology, a ratio of the second capacitance value to the first capacitance value in this application decreases from 9.3% to 3.7%, enhancing the anti-coupling capability of the first reset signal line Vi3 and thereby improving the stability of the reset signal transmitted by the first reset signal line Vi3.

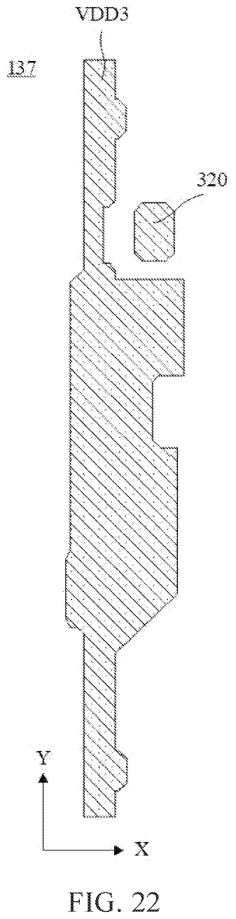

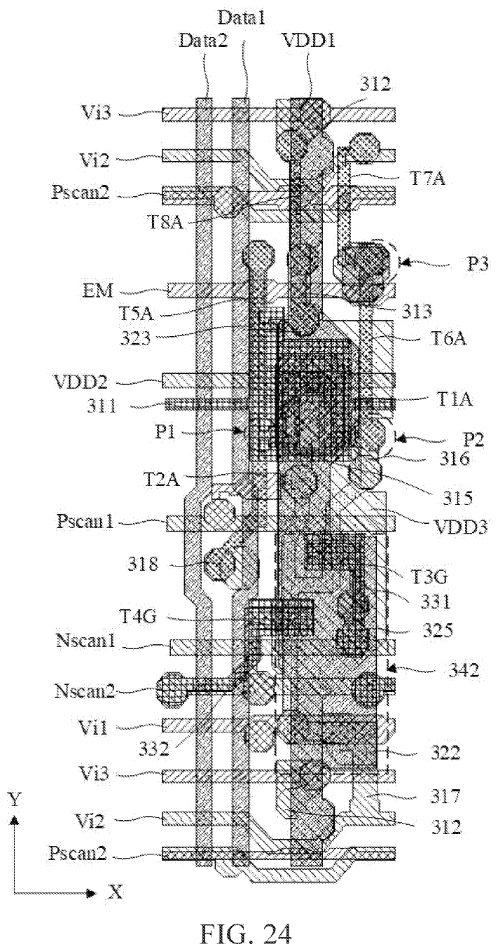

Referring to FIGS. 22 and 24, the third source-drain layer 137 can include a third high potential line VDD3 extending along the second direction Y. The third high potential line VDD3 is electrically connected to the second high potential line VDD2. The primary purpose of establishing the third high potential line VDD3 is to reduce the impedance of the wiring used for transmitting a constant high voltage level.

It should be noted that, in FIGS. 16 to 22, the first high potential line VDD1 in this application can be electrically connected to the second high potential line VDD2. Subsequently, the second high potential line VDD2 is electrically connected to the fourth plate Cst2 of the storage capacitor Cst, and the fourth plates Cst2 located in the same row are interconnected via the first electrical connection segment 311. Therefore, the wiring used for transmitting the constant high voltage level in this application involves four layers of metal, which include the fourth plate Cst2 and the first electrical connection segment 311 located in the second gate layer 127, the second high potential line VDD2 located in the first source-drain layer 133, the first high potential line VDD1 located in the second source-drain layer 135, and the third high potential line VDD3 located in the third source-drain layer 137. The fourth plate Cst2, the first electrical connection segment 311, and the second high potential line VDD2 all extend along the first direction X, while the first high potential line VDD1 and the third high potential line VDD3 extend along the second direction Y. Thus, this application utilizes a four-layer metal transmission for the constant high voltage level to form a crisscrossing mesh-like metal network, aiming to reduce the impedance of the wires and, consequently, minimize the loss of the constant high voltage level in the transmission lines.

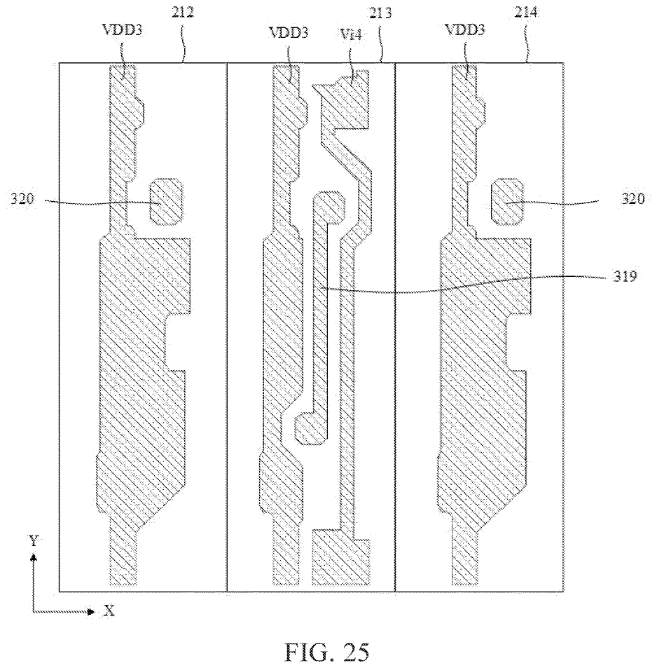

Referring to FIG. 25, the third source-drain layer 137 of this application includes a plurality of repeating units 137a, each corresponding to three sub-pixel units 211 arranged along the first direction X and adjacent to each other. For example, these three sub-pixel units 211 can be respectively referred to as the first sub-pixel unit 212, the second sub-pixel unit 213, and the third sub-pixel unit 214. Each repeating unit 137a can include the initial third high potential line VDD3 corresponds to the first sub-pixel unit 212, the final third high potential line VDD3 corresponds to the third sub-pixel unit 214, and the high potential line and the fourth reset signal line Vi4 corresponding to the second sub-pixel unit 213. The structure of the initial third high potential line VDD3 can be the same as the structure of the final third high potential line VDD3, but the structure of the middle third high potential lines VDD3 is different from the structure of the final third high potential line VDD3. A lateral width of the middle third high potential line VDD3 is smaller than a lateral width of the final third high potential line VDD3.

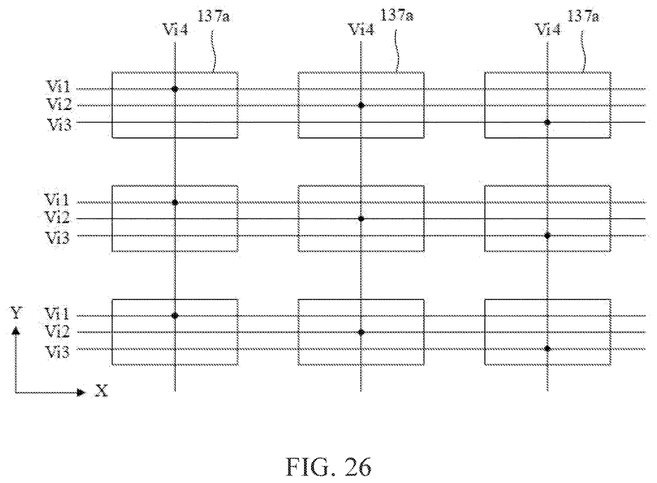

Referring to FIG. 25, each repeating unit 137a includes one vertical reset signal line and three horizontal reset signal lines. To reduce the impedance of the reset signal lines, the vertically arranged reset signal line can be electrically connected to one of the three horizontal reset signal lines. For example, as shown in FIG. 26, there are 3 rows of repeating units 137a, with each row including 3 repeating units 137a. Each repeating unit 137a contains one fourth reset signal line Vi4. The fourth reset signal line Vi4 in the first repeating unit 137a can be electrically connected to the third reset signal line Vi1 of each row. The fourth reset signal line Vi4 in the second repeating unit 137a can be electrically connected to the second reset signal line Vi2 of each row. The fourth reset signal line Vi4 in the third repeating unit 137a can be electrically connected to the first reset signal line Vi3 of each row. This configuration allows each horizontally arranged reset signal line to form an electrical connection with the fourth reset signal line Vi4, creating a crisscrossing metal mesh that reduces the impedance of the reset signal lines.

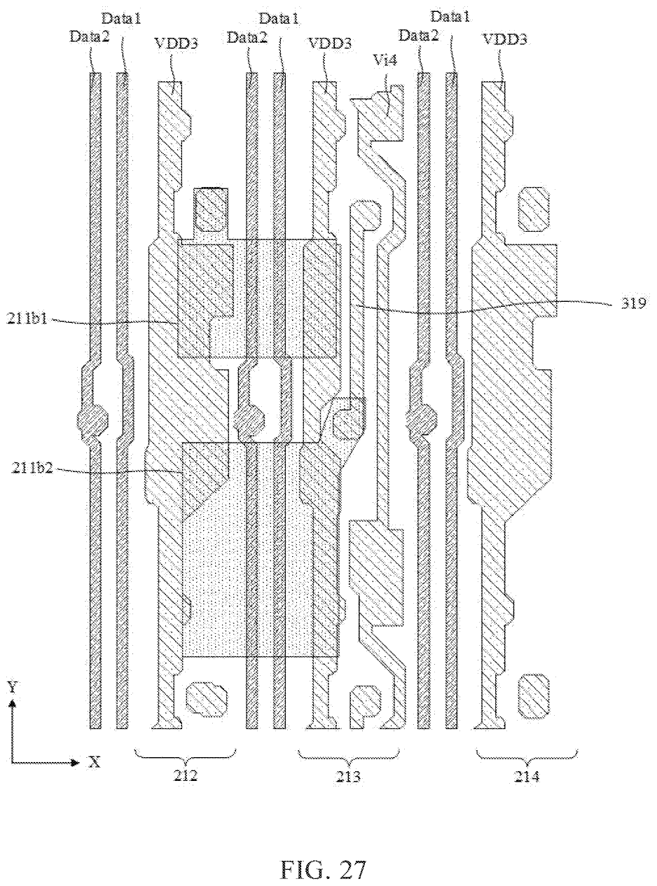

It should be noted that in FIG. 25, the first sub-pixel unit 212, the second sub-pixel unit 213, and the third sub-pixel unit 214 merely represent the positions of the pixel driving circuits 211a for the corresponding sub-pixel units 211, while the positions of the anodes within the sub-pixel units 211 may not be within the corresponding areas. For instance, as shown in FIG. 27, the pixel driving circuit 211a in the first sub-pixel unit 212 is electrically connected to the first anode 211b1, and the pixel driving circuit 211a in the second sub-pixel unit 213 is connected to the second anode 211b2. The first anode 211b1 and the second anode 211b2 are arranged along the second direction Y, and both the first anode 211b1 and the second anode 211b2 span across the first sub-pixel unit 212 and the second sub-pixel unit 213.

It should be noted that in FIG. 27, the third source-drain layer 137 can also include a ninth electrical connection segment 319 and a tenth electrical connection segment 320. The ninth electrical connection segment 319 is positioned between the fourth reset signal line Vi4 and the second third high potential line VDD3, while the tenth electrical connection segment 320 is located on one side of the initial and final high potential lines VDD3, and the tenth electrical connection segment 320 is arranged corresponding to the fourth electrical connection segment 314. The second source-drain layer 135 can further include an eleventh electrical connection segment 321. The second anode 211b2 can be electrically connected to the third connection point P3 in the first active layer 123 of the pixel driving circuit 211a of the second sub-pixel unit 213 through the ninth electrical connection segment 319, the eleventh electrical connection segment 321, and the fourth electrical connection segment 314 in the second sub-pixel unit 213. Similarly, the first anode 211b1 can be electrically connected to the third connection point P3 in the first active layer 123 of the pixel driving circuit 211a of the first sub-pixel unit 212 through the tenth electrical connection segment 320, the eleventh electrical connection segment 321, and the fourth electrical connection segment 314 in the first sub-pixel unit 212. Likewise, the connection method for the anode in the third sub-pixel unit 314 is similar to the connection method for the first anode 211b1.

The present application further provides a display device that includes the aforementioned display panel. The display device can be any product or component with a display function, such as mobile phones, tablets, televisions, monitors, laptops, digital photo frames, navigation systems, etc.

In the described embodiments, each has its focus, and parts not detailed in one embodiment can refer to the relevant descriptions in other embodiments.

A detailed introduction to a spliced display module and a manufacturing method, a display device has been provided in the embodiments of the present application. Specific examples have been used to explain the principles and implementation methods of this application. The explanations of the above embodiments are only intended to help understand the technical solutions of this application and its core ideas. Those skilled in the art should understand that they can still make modifications to the technical solutions recorded in the foregoing embodiments or equivalently replace some of the technical features; and these modifications or replacements do not depart from the essence of the technical solutions of the embodiments of this application.

What is claimed is:

1. A display panel, comprising a plurality of sub-pixel units, each of the sub-pixel units provided with a light-emitting device and a pixel driving circuit connected to the light-emitting device, wherein the pixel driving circuit comprises:
a switch transistor, a first electrode of the switch transistor connected to a first data signal line and a second electrode of the switch transistor connected to a first node;
a driving transistor, a first electrode of the driving transistor connected to the first node, a second electrode of the driving transistor connected to a second node, and a driving gate of the driving transistor connected to a third node;
a compensation transistor, a first electrode of the compensation transistor connected to the third node, and a second electrode of the compensation transistor connected to the second node;
a first reset transistor, a first electrode of the first reset transistor connected to a first reset signal line, and a second electrode of the first reset transistor connected to the first node; and
a first capacitor, a first plate of the first capacitor connected to the first reset signal line, and a second plate of the first capacitor connected to a first high potential line.

2. The display panel according to claim 1, further comprising:
a base substrate;
a first gate layer, disposed on one side of the base substrate;
a second gate layer, disposed on one side of the first gate layer away from the base substrate;
a third gate layer, disposed on one side of the second gate layer away from the first gate layer;
a first source-drain layer, disposed on one side of the third gate layer away from the second gate layer; and
a second source-drain layer, disposed on one side of the first source-drain layer away from the third gate layer;
wherein the first plate is disposed in at least one of the first gate layer and the first source-drain layer, and the second plate is disposed in the second source-drain layer.

3. The display panel according to claim 2, wherein the second source-drain layer comprises a plurality of first high potential lines arranged along a first direction and extending in a second direction; the first source-drain layer comprises a first sub-part of the first plate, one end of the first sub-part is electrically connected to the first reset signal line, and another end of the first sub-part is connected to an active part of the first reset transistor; an orthographic projection of the first sub-part projected on the second source-drain layer is at least partially located within the first high potential line, and an angle between the first direction and the second direction is greater than 0 degrees and less than or equal to 90 degrees.

4. The display panel according to claim 3, wherein the first gate layer comprises the first reset signal line extending along the first direction, the first source-drain layer comprises a second reset signal line extending along the first direction, and the second reset signal line and the first reset signal line spaced apart in the second direction,
wherein the first sub-part overlaps with a portion of the first reset signal line, and the first sub-part is disposed apart from the second reset signal line.

5. The display panel according to claim 4, wherein the second reset signal line comprises a horizontal segment, inclined segments, and a bypass segment, each of two ends of the bypass segment is connected to one of the inclined segments, and one end of each inclined segment away from the bypass segment is connected to the horizontal segment,
wherein a distance between the horizontal segment and the first reset signal line is smaller than a distance between the bypass segment and the second reset signal line, and the bypass segment is disposed corresponding to the first sub-part.

6. The display panel according to claim 5, wherein the first sub-part comprises a first inclined surface facing towards one side of the second reset signal line, the inclined segment comprises a second inclined surface facing towards the first sub-part, and the first inclined surface and the second inclined surface are parallel to each other.

7. The display panel according to claim 3, wherein a portion of the first reset signal line is repurposed as a second sub-part of the first plate, an orthographic projection of the second sub-part projected on the first source-drain layer avoids overlapping with the first sub-part, and an orthographic projection of the second sub-part projected on the second source-drain layer is located within the first high potential line.

8. The display panel according to claim 2, wherein the first high potential line comprises a first sub-plate and a second sub-plate arranged along the second direction; an orthographic projection of the drive gate projected on the first high potential line is located within the first sub-plate, while an orthographic projection of the first plate projected on the first high potential line is at least partially located within the second sub-plate;
wherein the second source-drain layer comprises the first data signal line extending along the second direction, and a distance between the first sub-plate and the first data signal line is greater than a distance between the second sub-plate and the first data signal line.

9. The display panel according to claim 1, wherein the pixel driving circuit further comprises:
a storage capacitor comprising a third plate and a fourth plate, wherein the third plate is connected to the third node, and the fourth plate is connected to the first high potential line;
a second reset transistor, a first electrode of the second reset transistor is connected to the second reset signal line, and a second electrode of the second reset transistor is connected to an anode of the light-emitting device;
a third reset transistor, wherein a first electrode of the third reset transistor is connected to the third reset signal line, and a second electrode of the third reset transistor is connected to the third node;
a first light-emitting transistor, wherein a first electrode of the first light-emitting transistor is connected to the first high potential line, and a second electrode of the first light-emitting transistor is connected to the first node, and a gate of the first light-emitting transistor is connected to a light-emitting signal line;
a second light-emitting transistor, wherein a first electrode of the second light-emitting transistor is connected to the second node, a second electrode of the second light-emitting transistor is connected to an anode of the light-emitting device, and a gate of the second light-emitting transistor is connected to the light-emitting signal line; and
a boost capacitor, comprising a fifth plate and a sixth plate, wherein the fifth plate is connected to the third node, and the sixth plate is connected to the second scan signal line.

10. The display panel according to claim 9, wherein a capacitance value of the first capacitor is smaller than a capacitance value of the storage capacitor, and a capacitance value of the boost capacitor is smaller than the capacitance value of the storage capacitor.

11. The display panel according to claim 9, wherein a first gate layer of the display panel comprises a light-emitting signal line, a third reset signal line, a first reset signal line, and a fourth scan signal line; the light-emitting signal line, the third reset signal line, the first reset signal line, and the fourth scan signal line all extend along the first direction; and the first reset signal line, the fourth scan signal line, the light-emitting signal line, and the third reset signal line are arranged at intervals along the second direction.

12. The display panel according to claim 11, wherein a first active layer of the display panel comprises a switch active part of the switch transistor, a drive active part of the driving transistor, a second reset active part of the second reset transistor, a first reset active part of the first reset transistor, a first light-emitting active part of the first light-emitting transistor, and a second light-emitting active part of the second light-emitting transistor;
wherein the switch active part, the drive active part, the second reset active part, the first light-emitting active part, and the second light-emitting active part are interconnected; the switch active part, the second reset active part, the first reset active part, the first light-emitting active part, and the second light-emitting active part extend along the second direction; and the drive active part is disposed between the first light-emitting active part and the second light-emitting active part.

13. The display panel according to claim 12, wherein a second gate layer of the display panel comprises a fourth plate of the storage capacitor, a first shading unit of the compensation transistor, and a second shading unit of the third reset transistor, arranged along the second direction; the fourth plate, the first shading unit, and the second shading unit are disposed between the light-emitting signal line and the third reset signal line; and the third plate is disposed close to the light-emitting signal line, the second shading unit is disposed close to the third reset signal line, and the first shading unit is disposed between the second shading unit and the fourth plate.

14. The display panel according to claim 13, wherein the second gate layer further comprises two first electrical connection segments disposed on two sides of the fourth plate, the two first electrical connection segments both extend along the first direction, and in two adjacent ones of the sub-pixel units arranged along the first direction, the fourth plates within the two adjacent sub-pixel units are electrically connected through the first electrical connection segment.

15. The display panel according to claim 13, wherein a second active layer of the display panel comprises a compensation active part of the compensation transistor and a third reset active part of the third reset transistor; both the compensation active part and the third reset active part extend along the second direction; and a first end of the compensation active part is connected to a first end of the third reset active part, and a second end of the third reset active part extends towards the third reset signal line and overlaps with the third reset signal line.

16. The display panel according to claim 15, wherein the second active layer further comprises a first extension segment and a second extension segment connected to a second end of the third reset active part; the first extension segment extends along the second direction and towards the storage capacitor, with the first extension segment being set apart from the storage capacitor; and the second extension segment extends along the first direction, and the second extension segment at least partially overlaps with the third reset signal line.

17. The display panel according to claim 15, wherein a third gate layer of the display panel comprises a compensation gate of the compensation transistor and a third reset gate of the third reset transistor; an area of the compensation gate is smaller than an area of the first shading unit, and an orthographic projection of the compensation gate projected on the first shading unit is located within the first shading unit; and an area of the third reset gate is smaller than an area of the second shading unit, and an orthographic projection of the third reset gate projected on the second shading unit is located within the second shading unit.

18. The display panel according to claim 17, wherein the third gate layer further comprises a first conductive segment connected to the compensation gate and a second conductive segment connected to the third reset gate; the first conductive segment extends along the second direction and towards a side away from the compensation gate, while the second conductive segment extends along the second direction and towards a side away from the third reset gate.

19. The display panel according to claim 18, wherein a first source-drain layer of the display panel comprises a second reset signal line, a fifth scan signal line, a second high potential line, a second scan signal line, a first scan signal line, and a third scan signal line, arranged along the second direction; and the second reset signal line, the fifth scan signal line, the second high potential line, the second scan signal line, the first scan signal line, and the third scan signal line all extend along the first direction.

20. A display device, comprising a display panel, the display panel comprising a plurality of sub-pixel units, each of the sub-pixel units provided with a light-emitting device and a pixel driving circuit connected to the light-emitting device, wherein the pixel driving circuit comprises:
a switch transistor, a first electrode of the switch transistor connected to a first data signal line and a second electrode of the switch transistor connected to a first node;
a driving transistor, a first electrode of the driving transistor connected to the first node, a second electrode of the driving transistor connected to a second node, and a driving gate of the driving transistor connected to a third node;
a compensation transistor, a first electrode of the compensation transistor connected to the third node, and a second electrode of the compensation transistor connected to the second node;
a first reset transistor, a first electrode of the first reset transistor connected to a first reset signal line, and a second electrode of the first reset transistor connected to the first node; and
a first capacitor, a first plate of the first capacitor connected to the first reset signal line, and a second plate of the first capacitor connected to a first high potential line.
